(19) United States
(12) Patent Application Publication
(10) Pub. No.: US 2026/0204316 A1
(43) Pub. Date: Jul. 16, 2026

(54) IN-MEMORY COMPUTING CIRCUIT FOR ACCUMLATION FUNCTIONS AND CONTENT ADDRESSABLE MEMORY (CAM) INCLUDING THE IN-MEMORY COMPUTING CIRCUIT

(71) Applicant: GlobalFoundries U.S. Inc., Malta, NY (US)

(72) Inventors: Steven Robert Soss, Saratoga Springs, NY (US); Thomas W. Andre, Saratoga Springs, NY (US); Siri Narla, Atlanta, GA (US)

(21) Appl. No.: 19/019,731

(22) Filed: Jan. 14, 2025

(51) Int. Cl. G11C 15/04; G11C 7/16

(52) U.S. Cl. CPC G11C 15/046; G11C 7/16

(57) ABSTRACT

An in-memory computing circuit structure can include an array of bit cells. Each bit cell includes: a first transistor and a first variable resistor series-connected between end nodes; and a second transistor and a second variable resistor series-connected between the end nodes. Within the columns, bit cells are series-connected in bit cell stacks, sense nodes are on the bit cell stacks, and analog-to-digital converters (ADCs) are connected to the sense nodes. Concurrent read operations are performed to sum resistances of selected variable resistors in the bit cells of the columns, respectively. The resulting currents on the sense nodes are provided as analog input signals to the ADCs. Each ADC for a column outputs a digital output signal indicating how close bit values stored in bit cells of the column are to matching input data signals applied to the rows. A content addressable memory (CAM) can include such a structure.

The present disclosure relates to in-memory computing and, more particularly, to embodiments of an in-memory computing circuit for accumulation functions, and to embodiments of a content addressable memory (CAM) including the in-memory computing circuit.

Traditionally, in-memory computing of multiplication functions has included application of input voltages to programmable resistors (such as memristors), respectively, in strings of bit cells (e.g., in each column of bit cells in an array). In response to the input voltages, the programmable resistors in each string of bit cells generate corresponding currents and these currents are added together down the string to generate an output current that corresponds to a solution for a matrix-vector multiplication function. However, this technique requires the programmable resistors to have relatively high resistance values in order to prevent high current generation. Furthermore, the output current from each string (which corresponds to the sum of the currents from the programmable resistors therein) is inherently non-transitive and, thus, requires further processing to make any linear algebraic assumptions.

### SUMMARY

Embodiments of in-memory computing structure disclosed herein can include an array of bit cells arranged in columns and rows. Each bit cell can include: end nodes; a first transistor and a first variable resistor connected in series between the end nodes; and a second transistor and a second variable resistor connected in series between the end nodes. Within the columns, the bit cells can be series-connected in bit cell stacks. The in-memory computing structure can also include sense nodes on the bit cell stacks and analog-to-digital converters connected to the sense nodes.

Some embodiments of an in-memory computing structure disclosed herein can include an array of bit cells arranged in columns and rows. Each bit cell can include: end nodes; a first transistor and a first variable resistor connected in series between the end nodes; and a second transistor and a second variable resistor connected in series between the end nodes. Within the columns, the bit cells can be series-connected in bit cell stacks. The in-memory computing structure can also include: sense nodes on the bit cell stacks; analog-to-digital converters connected to the sense nodes; and a comparator connected to the analog-to-digital converters.

Still other embodiments of an in-memory computing structure can include an array of bit cells arranged in columns and rows. Each bit cell can include: end nodes; a first transistor and a first variable resistor connected in series between the end nodes; and a second transistor and a second variable resistor connected in series between the end nodes. The array can be partitioned into multiple sub-arrays of the bit cells with each sub-array including a corresponding group of the rows. Within each sub-array, the bit cells in the columns can be series-connected in bit cell stacks. The in-memory computing structure can also include sense nodes on the bit cell stacks and analog-to-digital converters for the columns. Each analog-to-digital converter for a column can be connected to all sense nodes on all bit cell stacks of that column in all the different sub-arrays. The in-memory computing structure can also include a comparator connected to the analog-to-digital converters.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1, 2 and 3 are schematic diagrams illustrating disclosed embodiments of an in-memory computing circuit structure;

FIGS. 4A and 4B are illustrations of an example of a resistive random access memory (RRAM)-type variable resistor in different resistance states, respectively;

FIGS. 5A and 5B are illustrations of an example of a magnetic tunnel junction (MTJ)-type variable resistor in different resistance states, respectively;

FIGS. 6A and 6B are illustrations of an example phase change memory (PCM)-type variable resistor in different resistance states, respectively;

FIG. 7A is a schematic diagram illustrating a disclosed in-memory computing circuit structure implemented as a content addressable memory (CAM);

FIG. 7B is a graph illustrating a relationship between current and hamming distance in the CAM of FIG. 7A; and

FIG. 8 is a schematic diagram illustrating another disclosed in-memory computing circuit structure implemented as a CAM and specifically including array partitioning.

### DETAILED DESCRIPTION

As mentioned above, traditionally, in-memory computing of multiplication functions has included application of input voltages to programmable resistors (such as memristors), respectively, in strings of bit cells (e.g., in each column of bit cells in an array). In response to the input voltages, the programmable resistors in each string of bit cells generate corresponding currents and these currents are added together down the string to generate an output current that corresponds to a solution for a matrix-vector multiplication function. However, this technique requires the programmable resistors to have relatively high resistance values in order to prevent high current generation. Furthermore, the output current from each string (which corresponds to the sum of the currents from the memristors therein) is inherently non-transitive and, thus, requires further processing to make any linear algebraic assumptions.

In view of the foregoing disclosed herein are embodiments of an in-memory computing circuit structure (hereinafter referred to as the structure) for performing accumulation functions by summing resistances and for generating digital output signals (Douts) based thereon. The structure can include an array of bit cells arranged in columns and rows. Each bit cell can include at least: a first transistor and a first variable resistor series-connected between end nodes; and a second transistor and a second variable resistor also series-connected between the end nodes. Within the columns, bit cells are series-connected end node-to-end node in bit cell stacks (also referred to herein as bit cell strings). The structure can also include sense nodes on the bit cell stacks and analog-to-digital converters (ADCs) connected to the sense nodes. The structure can include additional circuitry, as discussed in greater detail below, to facilitate the performance of memory operations (e.g., write and read operations).

Write operations can specifically be performed so that, within any given bit cell, the first and second variable resistor have opposite resistance states to store opposite bit values (e.g., the first variable resistor has a low resistance state (LRS) to store one bit value and the second variable resistor has a high resistance state (HRS) to store a different bit value or vice versa). Read operations can be performed across the bit cells in the columns, concurrently. Specifically, during such read operations, input data signals (Dins) to the rows, respectively, can be such that, within each row, either the first transistors of the bit cells in the row or the second transistors of the bit cells in the row are turned on.

Thus, within each bit cell in a row, current flows through the same selected transistor and variable resistor (i.e., either through all first transistors and first variable resistors of all bit cells in the row or all second transistors and second variable resistors of all bit cells in the row). As a result, the resistances of the selected variable resistors of the bit cells in a column are accumulated with the total sum being represented by the amount of current generated across the column's sense node. Such currents are provided as an analog input signal to the ADCs and, in response to the analog input signals, the ADCs output digital output signals (Douts). Each Dout from an ADC of a column effectively indicates how close bit values stored in the bit cells of that column are to matching the Dins applied to the rows. With a structure as described above, the currents across the bit cell stacks are relatively small and the bit cells are inherently transitive in nature.

Also disclosed herein are embodiments of a content addressable memory (CAM) including the in-memory computing circuit structure and a comparator for comparing the Douts from the ADCs to determine which one of the columns stores bit values that most closely match the Dins applied to the rows. For example, the bit cells in the columns can store the bit values of different look-up vectors, respectively, and the Dins applied to the rows can correspond to the bit values in a hypervector to be matched during a classification look-up. In this case, the Douts from the ADCs can be compared to determine which of the look-up vectors most closely matches the hypervector. Optionally, within the CAM, the array of bit cells can be partitioned into multiple sub-arrays, as discussed in greater detail below.

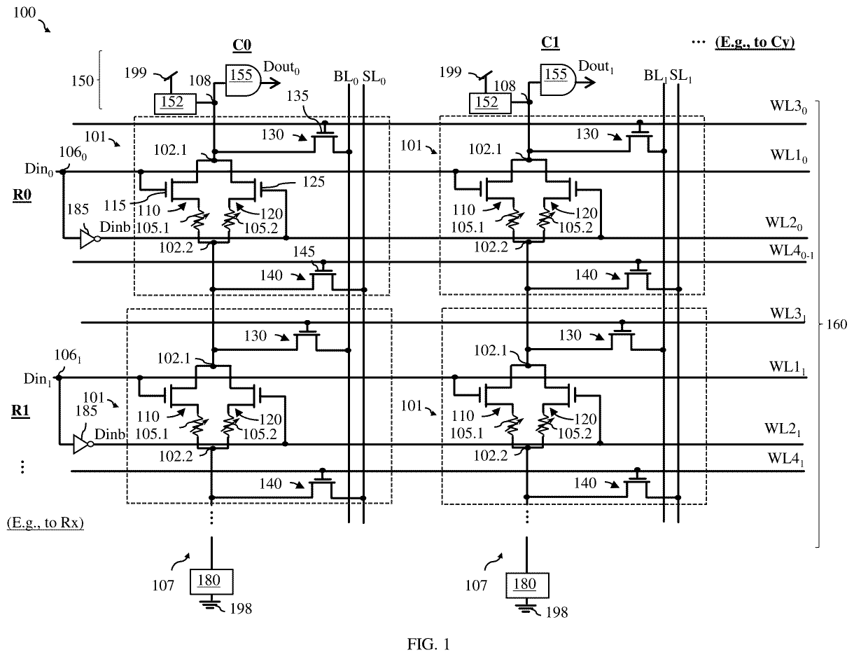

More particularly, FIGS. 1, 2 and 3 are schematic diagrams illustrating disclosed embodiments of an in-memory computing circuit structure (hereinafter referred to as the structure) 100, 200, and 300, respectively, for performing accumulation functions by summing resistances and for generating digital output signals (Douts) based thereon. Structure 100, 200, 300 can include an array of bit cells 101, 201, 301 arranged in columns (e.g., see columns C0-Cy) and rows (e.g., see rows R0-Rx).

Each bit cell 101, 201, 301 can include end nodes 102.1-102.2, 202.1-202.2, 302.1-302.2. Each bit cell 101, 201, 301 can include a first transistor 110, 210, 310 (also referred to herein as a first read-write access transistor) and a first variable resistor 105.1, 205.1, 305.1 connected in series between end nodes 102.1-102.2, 202.1-202.2, 302.1-302.2. Each bit cell 101, 201, 301 can also include a second transistor 120, 220, 320 (also referred to herein as a second read-write access transistor) and a second variable resistor 105.2, 205.2, 305.2 connected in series between end nodes 102.1-102.2, 202.1-202.2, 302.1-302.2. More specifically, first transistor 110, 210, 310 can include at least a first channel region positioned laterally between first source/drain regions and a first gate 115, 215, 315 adjacent to the first channel region. One first source/drain region can be electrically connected to first end node 102.1, 202.1, 302.1. First variable resistor 105.1, 205.1, 305.1 can be electrically connected to the other first source/drain region and to second end node 102.2, 202.2, 302.2. Similarly, second transistor 120, 220, 320 can include at least a second channel region positioned laterally between second source/drain regions and a second gate 125, 225, 325 adjacent to the second channel region. One second source/drain region can be electrically connected to first end node 102.1, 202.1, 302.1. Second variable resistor 105.2, 205.2, 305.2 can be electrically connected to the other second source/drain region and to second end node 102.2, 202.2, 302.2. Thus, the series-connected first transistor and first variable resistor and the series-connected second transistor and second variable resistor in each bit cell are electrically connected in parallel between the end nodes.

First and second variable resistors 105.1-105.2, 205.1-205.2, 305.1-305.2 can be any now known or subsequently developed type of resistor having a selectively variable resistance and, particularly, having a resistance that can be switched between at least two different resistance states including a high resistance state (HRS) and a low resistance state (LRS). The HRS can indicate a stored bit with a first bit value (e.g., a bit value of “0”) and the LRS can indicate a stored bit with a second bit value (e.g., a bit value of “1”). Such variable resistors include, but are not limited to, resistive random access memory (RRAM)-type variable resistors (e.g., also referred to as memristors), magnetic tunnel junction (MTJ)-type variable resistors, and phase change memory (PCM)-type variable resistor. The first and second variable resistors 105.1-105.2, 205.1-205.2, 305.1-305 can be independently switchable between the two different resistance states (i.e., between the two different resistances).

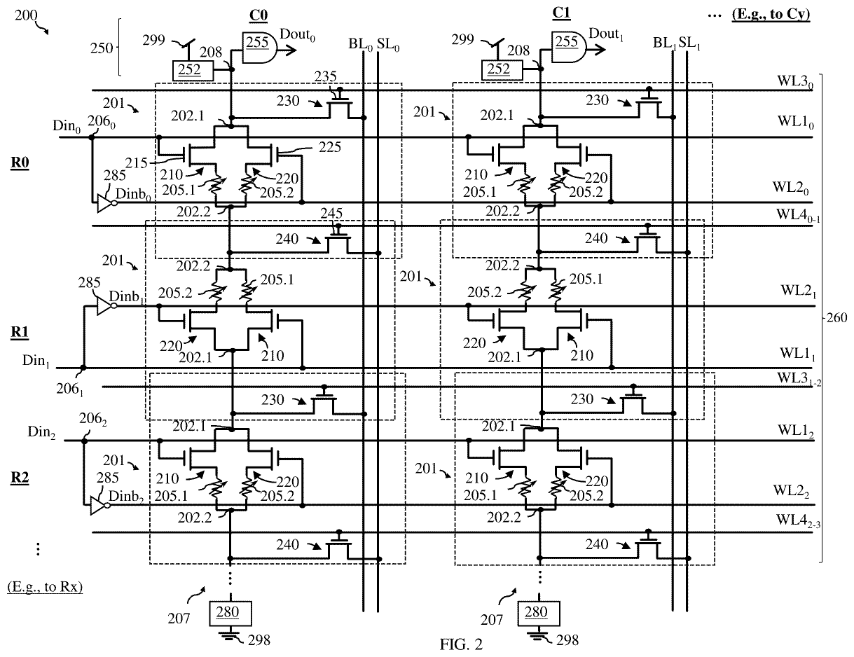

FIGS. 4A and 4B are cross-section diagrams illustrating an example of an RRAM-type variable resistor 405 in different resistance states, respectively. Such an RRAM-type variable resistor 405 is also typically a back end of the line (BEOL) multi-layer structure, which includes two metal layers 412 and 414 separated by a dielectric layer 413 (e.g., hafnium oxide (HfOₓ) or some other suitable oxide layer, also referred to as a switching layer). Depending upon the biasing conditions on metal layers 412 and 414 during a write operation, ions in dielectric layer 413 may migrate to: (a) break-up a conductive filament 415 extending between metal layers 412 and 414 so that RRAM-type variable resistor 405 is in the HRS, thereby storing one bit value (e.g., a logic value of “0”) (e.g., see FIG. 4A) or (b) grow conductive filament(s) 415 in dielectric layer 413 extending between metal layers 412 and 414 so that RRAM-type variable resistor 405 is the LRS, thereby storing a different bit value (e.g., a logic value of “1”) (e.g., see FIG. 4B).

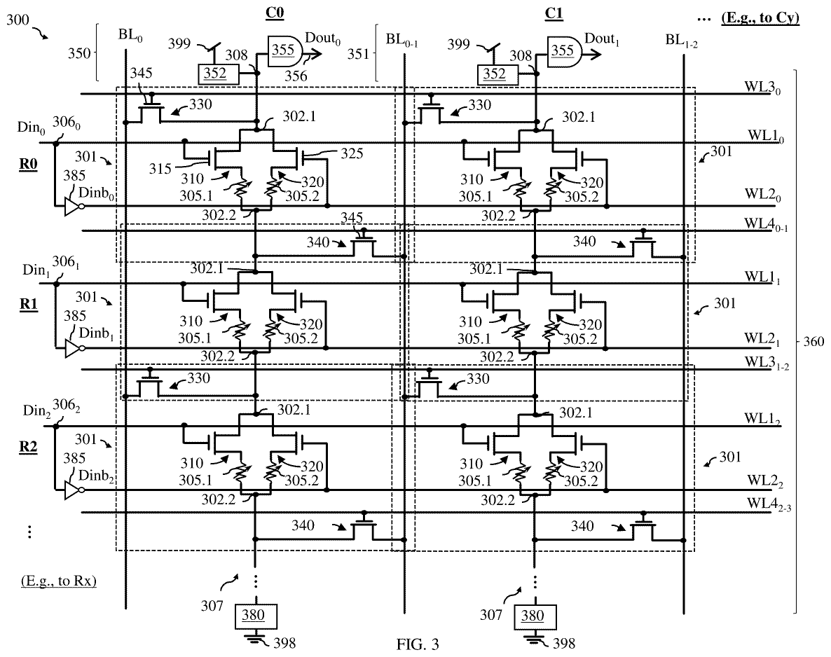

FIGS. 5A and 5B are cross-section diagrams illustrating an example of a MTJ-type variable resistor 505 in different resistance states, respectively. Such a MTJ-type variable resistor 505 is typically a BEOL multi-layer structure, which includes a free ferromagnetic layer 514 (also referred to as a switchable layer) and a fixed ferromagnetic layer 512 (also referred to as a pinned layer) separated by a thin dielectric layer 513 (e.g., a thin oxide layer or some other suitable type of dielectric layer). Depending upon the biasing conditions on ferromagnetic layers 512 and 514 during a write operation, MTJ-type variable resistor 505 may switch between an anti-parallel resistance (RAP) state (i.e., a HRS, as shown in FIG. 5A) and a parallel resistance (RP) state (i.e., a LRS, as shown in FIG. 5B).

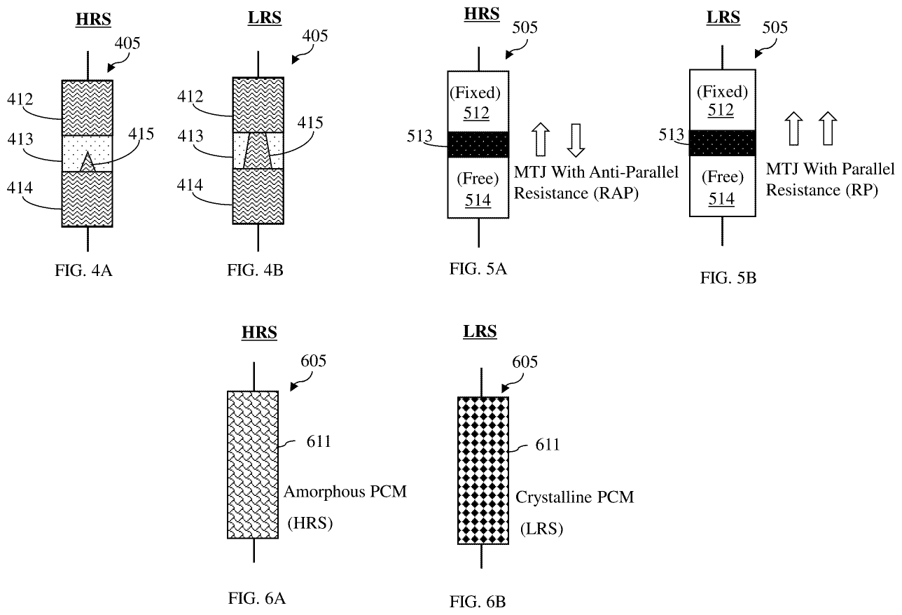

FIGS. 6A and 6B are cross-section diagrams illustrating an example PCM-type variable resistor 605 in different resistance states, respectively. Such a PCM-type variable resistor employs a phase change material 611 (e.g., a chalcogenide compound) with programmable structural phases that exhibit different resistances. Depending upon the biasing conditions on opposite terminals of resistor and, thus, the local temperature, the PCM may switch between an amorphous phase (i.e., a HRS, as shown in FIG. 6A) and a crystalline phase (i.e., a LRS, as shown in FIG. 6B).

Any of the above described variable resistors 405, 505, 605 could be incorporated into bit cell 101, 201, 301 as first and second variable resistors 105.1-105.2, 205.1-205.2, 305.1-305.2. Such variable resistors and the biasing conditions necessary to switch resistance states thereof during write operations are known in the art. Thus, more specific details have been omitted from this specification in order to allow the reader to focus on the salient aspects of the disclosed embodiments related, for example, to the structure of bit cell 101 itself and to its incorporation into an in-memory computing circuit.

It should be noted that, within each of the columns (C0, C1, etc.), all bit cells 101, 201, 301 are electrically connected in series, end node-to-end node, to form corresponding bit cell stacks 107, 207, 307. As illustrated, within these bit cell stacks 107, 207, 307, the specific end node-to-end node connections may vary depending upon the embodiment. For example, in the bit cell stacks 107 of structure 100 of FIGS. 1 and 307 of structure 300 of FIG. 3, second end node 102.2, 302.2 of bit cell 101, 301 in R0 is electrically connected to first end node 102.1, 302.1 of bit cell 101, 301 in R1, second end node 102.2, 302.2 of bit cell 101, 301 in R1 is electrically connected to first end node 102.1, 302.1 of bit cell 101, 301 in R2, and so on. However, in the bit cell stacks 207 of structure 200 of FIG. 2, second end node 202.2 of bit cell 101 in R0 is electrically connected to second end node 102.2 of bit cell 201 in R1, first end node 202.1 of bit cell 201 in R1 is electrically connected to first end node 202.1 of bit cell 201 in R2, and so on.

In any case, structure 100, 200, 300 can further include footer devices 180, 280, 380 and analog-to-digital converters (ADCs) 155, 255, 355 for the columns. Specifically, bit cell stacks 107, 207, 307 can be series-connected between footer devices 180, 280, 380 and sense nodes 108, 208, 308 for the columns, respectively. Footer devices 180, 280, 380 can be selectively controllable to connect bit cell stacks 107, 207, 307 to ground 198, 298, 398 during a read operation and to disconnect them from ground 198, 298, 398 during a write operation (as discussed in greater detail below). In some embodiments, each footer device 180, 280, 380 could be an N-type field effect transistor (NFET). Each NFET footer device could include: source/drain regions, which are connected to the last bit cell in Rx and to ground 198, 298, 398, respectively; and a gate, which is connected to receive a read enable signal (RDen).

Optionally, all footer devices 180, 280, 380 could be connected to receive the same RDen so that they concurrently connect the bit cell stacks 107, 207, 307 to ground or concurrently disconnect them from ground. Alternatively, footer devices 180, 280, 380 could have any other suitable footer device configuration. For example, each footer device 180, 280, 380 could include multiple NFETs, which are connected between a bit cell stack 107, 207, 307 and ground and which are controlled by the same RDen. Alternatively, each footer device 180, 280, 380 could include a transmission gate including an NFET and a P-type field effect transistor (PFET), which are connected in parallel between a bit cell stack 107, 207, 307 and ground and which are controlled by RDen and RDenb, respectively. Sense nodes 108, 208, 308 can be electrically connected to the ADCs 155, 255, 355 for the columns, respectively, and can further be electrically connected to a positive voltage rail 199, 299, 399 (e.g., via an optional voltage regulator 152, 252, 352).

Structure 100, 200, 300 can include third and fourth transistors 130-140, 230-240, 330-340 (also referred to herein as write access transistors), which are within or shared between bit cells 101, 201, 301 in the array depending upon the embodiment (as discussed in greater detail below). Generally, each third transistor 130, 230, 330 can include at least a third channel region positioned laterally between third source/drain regions and a third gate 135, 235, 335 adjacent to the third channel region. Similarly, each fourth transistor 140, 240, 340 can include at least a fourth channel region positioned laterally between fourth source/drain regions and a fourth gate 145, 245, 345 adjacent to the fourth channel region. Structure 100, 200, 300 can further include multiple word lines and either multiple source line-bit line pairs or multiple bit line-bit line pairs. The particular configuration can vary depending upon the embodiment, as discussed in greater detail below.

For example, referring to FIG. 1, structure 100 can include four word lines per row and, particularly, a first word line, a second word line, a third word line and a fourth word line for each row. For example, see WL1₀, WL2₀, WL3₀, and WL4₀ for R0, WL1₁, WL2₁, WL3₁, and WL4₁ for R1, and so on. Structure 100 can include also include a bit line-source line pair for each column. For example, see BL₀ and SL₀ for C0, BL₁ and SL₁ for C1, and so on. Each first word line WL1₀, WL1₁, etc., for each row R0, R1, etc., can be electrically connected to the first gates 115 of all first transistors 110 of all bit cells 101 in that row. Similarly, each second word line WL2₀, WL2₁, etc., for each row R0, R1, etc. can be electrically connected to the second gates 125 of all second transistors 120 of all bit cells 101 in that row. Each bit cell 101 can further include a third transistor 130 and a fourth transistor 140 of its own. Within each column, the third transistor 130 of each bit cell 101 can be electrically connected between the BL for the column and its first end node 102.1. Additionally, the fourth transistor 140 of each bit cell 101 can be electrically connected between the SL for the column and its second end node 102.2. Each third word line WL3₀, WL3₁, etc., for each row R0, R1, etc. can be electrically connected to the third gates 135 of all third transistors 130 of all bit cells 101 in that row. Similarly, each fourth word line WL4₀, WL4₁, etc., for each row R0, R1, etc. can be electrically connected to the fourth gates 145 of all fourth transistors 140 of all bit cells 101 in that row.

Alternatively, referring to FIG. 2, structure 200 can include a combination of shared third and fourth transistors 230 and 240 between bit cells 201 in adjacent rows, first and second word lines for each row, shared third or fourth word lines between adjacent rows, and bit line-source line pairs for each column. For example, see WL1₀ and WL2₀ for R0, WL1₁ and WL2₁ for R1, and so on. See also WL3₀ for R0 alone, WL4₀₋₁ shared between R0 and R1, WL3₁₋₂ shared between R1 and R2, WL4₂₋₃ is shared between R2 and R3, and so on. With this configuration, within each column, bit cell 201 in R0 has its own third transistor 230, which is electrically between the BL for the column and its first end node 202.1. However, in subsequent rows of the same column, the fourth transistor 240 is shared between adjacent bit cells in R0 and R1 and, particularly, is electrically connected between the SL for the column and the junction between second end nodes 202.2 of bit cells 201 in R0 and R1; the third transistor 230 is shared between adjacent bit cells in R1 and R2 and, particularly, is electrically connected between the BL for the column and the junction between first end nodes 202.1 of bit cells 201 in R1 and R2; the fourth transistor 240 is shared between adjacent bit cells in R2 and R3 and, particularly, is electrically connected between the SL for the column and the junction between second end nodes 202.2 of bit cells 201 in R2 and R3; and so on. In any case, each first word line WL1₀, WL1₁, etc., for each row R0, R1, etc. can be electrically connected to the first gates 215 of all first transistors 210 of all bit cells 201 in that row. Similarly, each second word line WL2₀, WL2₁, etc., for each row R0, R1, etc. can be electrically connected to the second gates 225 of all second transistors 220 of all bit cells 101 in that row. Furthermore, each third word line WL3₀, WL3₁₋₂, etc. can be electrically connected to the third gates of all third transistors 230 along a same line. Furthermore, each fourth word line WL4₀₋₁, WL4₂₋₃, etc. can similarly be electrically connected to the fourth gates of all fourth transistors 240 along a same line.

Alternatively, referring to FIG. 3, structure 300 can include a combination of shared third and fourth transistors 330 and 340 between bit cells 301, first and second word lines for each row, shared third or fourth word lines between adjacent rows, and bit line-bit line pairs for each column. For example, see WL1₀ and WL2₀ for R0, WL1₁ and WL2₁ for R1, and so on. See also WL3₀ for R0 alone, WL4₀₋₁ shared between R0 and R1, WL3₁₋₂ shared between R1 and R2, WL4₂₋₃ is shared between R2 and R3, and so on. With this configuration, within each column, bit cell 301 in R0 has its own third transistor 330, which is electrically between one BL in the pair for the column and its first end node 302.1. However, in subsequent rows of the same column, a fourth transistor 340 is shared between adjacent bit cells in R0 and R1 and, particularly, is electrically connected between the other BL in the pair for the column and a junction between a second end node 302.2 of bit cell 301 in R0 and first end node 302.1 in bit cell 301 in R1; a third transistor 330 is shared between adjacent bit cells in R1 and R2 and, particularly, is electrically connected between one BL in the pair for the column and the junction between the second end node 302.2 of bit cell 301 in R1 and first end node 302.1 of bit cell 301 in R2; a fourth transistor 340 is shared between adjacent bit cells in R2 and R3 and, particularly, is electrically connected between the other BL in the pair for the column and a junction between the second end node 302.2 of bit cell 301 in R2 and the first end node 302.1 of bit cell 301 in R3; and so on.

It should be noted that, within structure 300, adjacent columns may also share BLs. That is, as illustrated, the bit line-bit line pair for C0 is BL₀ and BL₀₋₁, the bit line-bit line pair for C1 is BL₀₋₁ (shared with C0) and BL₁₋₂, and so on. In any case, each first word line WL1₀, WL1₁, etc., for each row R0, R1, etc. can be electrically connected to the first gates 315 of all first transistors 310 of all bit cells 301 in that row. Similarly, each second word line WL2₀, WL2₁, etc., for each row R0, R1, etc. can be electrically connected to the second gates 325 of all second transistors 320 of all bit cells 101 in that row. Furthermore, each third word line WL3₀, WL3₁₋₂, etc. can be electrically connected to the third gates of all third transistors 330 along a same line and each fourth word line WL4₀₋₁, WL4₂₋₃, etc. can similarly be electrically connected to the fourth gates of all fourth transistors 340 along a same line.

It should be understood that, since structures 200 and 300 include fewer write access transistors and word lines as compared to the write access transistors and word lines in structure 100 of FIG. 1 and since structure 300 also includes fewer BL-BL pairs as compared to the SL-BL pairs in structure 100, structures 200 and 300 will consume less area than structure 100.

Referring again to FIGS. 1, 2, and 3 in combination, in some embodiments, the four transistors 110-140, 210-240, 310-340 within or shared between the bit cells in structure 100, 200, 300 can all be N-type field effect transistors (NFETs) (as shown). That is, in each of the transistors 110-140, 210-240, 310-340, the source/drain regions can have N-type conductivity at a relatively high conductivity level and the channel region can have either P-type conductivity at a relatively low conductivity level (or alternatively can be an intrinsic channel region). Those skilled in the art will recognize that a positive gate-source voltage (VGS) can be employed to switch an NFET to a conductive state and a negative VGS can be employed to switch an NFET. Alternatively, at least first transistor 110, 210, 310 and second transistor 120, 220, 320 could be P-type field effect transistors (PFETs) (not shown) or a PFET and an NFET (or vice versa) (also not shown).

In any case, structure 100, 200, 300 should be configured so that, during a memory operation (e.g., a read operation or a write operation), either the first transistor 110, 210, 310 in a bit cell 101, 201, 301 at issue is turned on and the second transistor 120, 220, 320 is turned off or vice versa. Thus, for example, in embodiments described above, where first and second transistors 110-120, 210-220, 310-320 have the same type conductivity (e.g., both NFETs, as illustrated, or both PFETs), structure 100, 200, 300 may also include inverters 185, 285, 385 for the rows, respectively. Each inverter 185, 285, 385 can include an input terminal, which is electrically connected to a data input node on a first word line for the row (e.g., see data input node 106₀ on WL1₀, 106₁ on WL1₁, and so on in structure 100; see data input node 206₀ on WL1₀, 206₁ on WL1₁, and so on in structure 200; see data input node 306₀ on WL1₀, 306₁ on WL1₁, and so on in structure 300) and an output terminal, which are electrically connected to the second word line for the same row. Each data input node and thereby each first word line can be electrically connected to receive a row-specific data input signal (e.g., see data input signals Din₀, Din₁, and so on). Each inverter 185, 285, 385 can invert a received data input signal and can output a corresponding row-specific inverted data input signal (e.g., see inverted data input signals Dinb₀, Dinb₁, and so on) to a corresponding second word line. As a result, only the first word line or second word line in a given row will be high and, thus, only the first transistors of the bit cells or the second transistors of the bit cells in that row will be turned on. Alternatively, in embodiments where first and second transistors 110-120, 210-220, 310-320 have different type conductivities (e.g., one NFET and one PFET), structure 100, 200, 300 may be devoid of inverters and instead the first word line and the second word line of each row can be electrically connected so as to receive the same data input signal (not shown).

Referring again to FIGS. 1, 2 and 3, structure 100, 200, 300 can further include additional components including, but not limited to, peripheral circuitry connected to the array and a controller in communication with the peripheral circuit. These additional components can be configured to facilitate performance of memory operations in the bit cells by establishing operation-dependent biasing conditions on the various WLs and SL-BL pairs or BL-BL pairs, as applicable. Generally, the memory operations can include write operations directed to each bit cell in order to establish opposite resistance states in the first variable resistor and the second variable resistor therein. The memory operations can also include read operations concurrently directed to the columns to perform accumulation functions. Specifically, within each column, a read operation can be performed to sum the resistances of selected variable resistors and, particularly, to sum the resistances of one variable resistor only from each bit cell in the column. Controllers and peripheral circuity configured to establish biasing conditions on WLs, BLs, and SLs, as necessary, during memory operations are known in the art. Thus, the details thereof have been omitted from the specification and figures in order to allow the reader to focus on the salient aspect of the disclosed embodiments.

More particularly, memory operations in structure 100, 200, 300 can include first and second write operations directed to each bit cell 101, 201, 301 to establish opposite resistance states in the first and second variable resistors 105.1-105.2, 205.1-205.2, 305.1-305.2 in each bit cell 101, 201, 301 (e.g., a LRS in the first variable resistor to store a bit value of “1” and the HRS in the second variable resistor to store a bit value of “1” or vice versa). It should be noted that during these write operations, the footer devices 180, 280, 380 can be maintained in off-states so that the bit cell stacks 107, 207, 307 in each column are disconnected from ground 198, 298, 398.

During the first write operation directed to the first variable resistor 105.1, 205.1, 305.1 in a selected bit cell 101, 201, 301, word line voltages can be established to: turn on the write access transistors (i.e., the third and fourth transistors 130-140, 230-240, 330-340) in or shared with the selected bit cell 101, 201, 301; turn on the first transistor 110, 210, 310 of the selected bit cell 101, 201, 301; and turn off the second transistor 120, 220, 320 of the selected bit cell 101, 201, 301. Appropriate biasing conditions can further be established on the SL-BL pair (or BL-BL pair, as applicable) connected to the selected bit cell 101, 201, 301 in order to achieve the desired resistance state in the first variable resistor 105.1, 205.1, 305.1 (e.g., either LRS or HRS). During a second write operation directed to the second variable resistor 105.2, 205.2, 305.2 in the selected bit cell 101, 201, 301, word line voltages can be established to: turn on the write access transistors (i.e., the third and fourth transistors 130-140, 230-240, 330-340) in or shared with the selected bit cell 101, 201, 301; turn off the first transistor 110, 210, 310 of the selected bit cell 101, 201, 301; and turn on the second transistor 120, 220, 320 of the selected bit cell 101, 201, 301.

Appropriate biasing conditions can further be established on the SL-BL pair (or BL-BL pair, as applicable) connected to the selected bit cell 101, 201, 301 in order to achieve the opposite resistance state in the second variable resistor 105.2, 205.2, 305.2. That is, if the first write operation causes the first variable resistor 105.1, 205.1, 305.1 to have the LRS, the second write operation can cause the second variable resistor 105.2, 205.2, 305.2 to have the HRS or vice versa. Those skilled in the art will recognize that the word line voltage levels and the biasing conditions on the SL-BL pair (or BL-BL pair) will vary depending upon the conductivity type of transistors 110-140, 210-240, 310-340, and the type of variable resistors employed.

In any case, once the first and second write operations are completed for all of the bit cells 101, 201, 301 in array 160, 260, 360, memory operations in 100, 200, 300 can further include read operations directed to across the bit cells in the columns, concurrently. Specifically, read operations are directed to the columns and, particularly, to the bit cells of the bit cell stacks the different columns at the same time. Within each column, the read operation results in summing of the following resistances: the resistance of first variable resistor 105.1, 205.1, 305.1 or second variable resistor 105.2, 205.2, 305.2 of bit cell 101, 201, 301 in R0, the resistance of first variable resistor 105.1, 205.1, 305.1 or second variable resistor 105.2, 205.2, 305.2 of bit cell 101, 201, 301 in R1 of C0; and so on. To accomplish these read operations row-specific data input signals can be applied to data input nodes on first word lines of the rows, respectively (e.g., see Din₀ on data input node 106₀, 206₀, 306₀ of WL1₀ for R0, Din₁ on data input node 106₁, 206₁, 306₀ of WL1₁ for R1, and so on).

It should be understood that the bit values of these row-specific data input signals can vary from row to row. Furthermore, it should be understood that depending upon the bit value of the data input signal applied to the data input node on the first word line of a given row, either the first transistors 110, 210, 310 of all the bit cells 101, 201, 301 in that row or the second transistors 120, 220, 320 of the bit cells 101, 201, 301 in that row will turn on. For example, as illustrated in FIGS. 1-3, with inverters 185, 285, 385 connected between the first word lines and the second word line and with all four transistors 110-140, 210-240, 310-340 are NFETs, if the data input signal on the data input node of a first word line for a given row is high, then the first transistors 110, 210, 310 of all the bit cells 101, 201, 301 in that row will turn on and the second transistors 120, 220, 320 will turn off. However, if the data input signal on the data input node of the first word line for the given row is low, then the first transistors 110, 210, 310 of all the bit cells 101, 201, 301 in that row will turn off and the second transistors 120, 220, 320 will turn on. Regardless, within each bit cell 101, 201, 301 in each column, either the first transistor 110, 210, 310 or the second transistor 120, 220, 320 will switch to an on-state and current will flow through the bit cell stack 107, 207, 307 to ground 198, 298, 398.

The amount of current flowing through each bit cell stack 107, 207, 307 will be proportional to the sum of the resistances of the variable resistors through which the current passes. It should be understood that the value of the sum of resistances will depend on which of the two variable resistors in each bit cell has the LRS and which has the HRS and also on the bit values of the data input signals. As mentioned above, sense nodes 108, 208, 308 for the columns can be electrically connected to ADCs 155, 255, 355 for the columns. During the read operations, ADCs 155, 255, 355 can receive, as analog input signals, sensed currents from sense nodes 108, 208, 308 and can further generate and output corresponding digital output signals based thereon(e.g., see Dout₀, Dout₁, and so on).

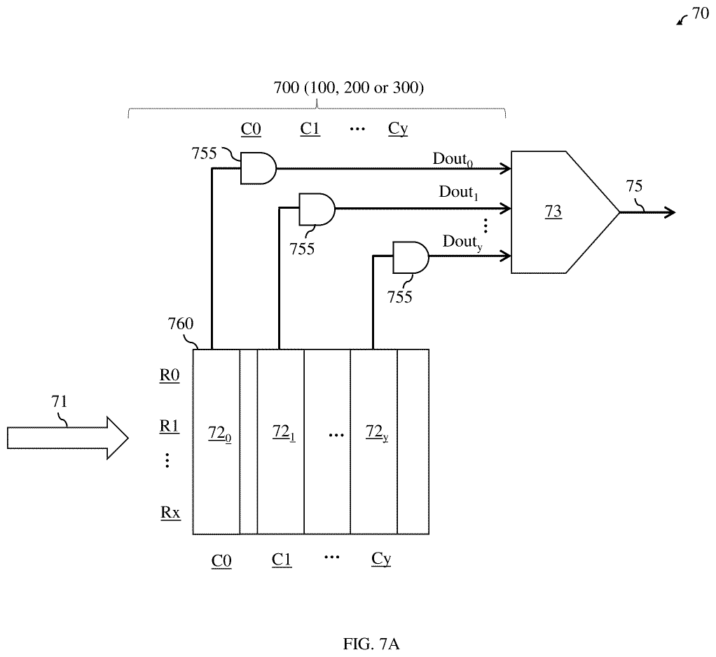

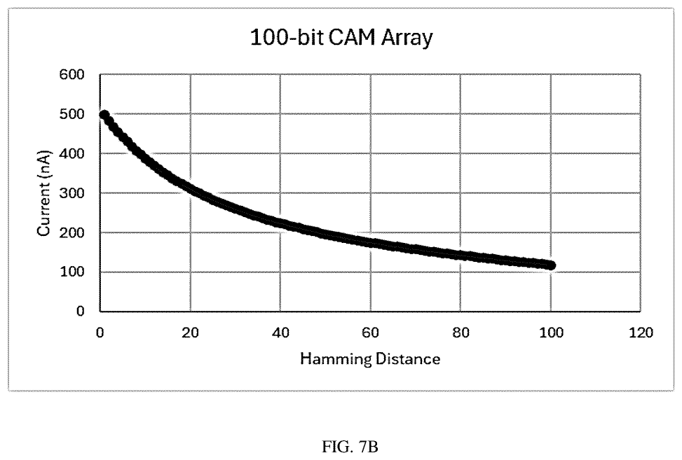

FIG. 7A is a schematic diagram illustrating a disclosed in-memory computing circuit structure (e.g., structure 100 of FIGS. 1, 200 of FIG. 3, or 300 of FIG. 3) implemented as a content addressable memory (CAM) 70.

More particularly, referring to FIG. 7A, a CAM 70 can include an in-memory computing structure 700 (e.g., such as structures 100 of FIGS. 1, 200 of FIG. 2, or 300 of FIG. 3 described in detail above). Generally, structure 700 includes, but is not limited to: an array 760 of bit cells arranged in columns (e.g., C0-Cy) and rows (R0-Rx) (again as discussed in detail above and described in any of FIG. 1, 2 or 3); and ADCs 755 for the columns. It should be understood that some of the components of structure 700 have been omitted from CAM 70 of FIG. 7 in order to avoid clutter in the figures and allow the reader to focus on the salient aspects of the disclosed embodiment related specifically to CAM operation. In any case, CAM 70 can further include a comparator 73. Comparator 73 can include: multiple input terminals, which are connected to receive digital output signals from ADCs 755 of the columns, respectively; and an output terminal for outputting a match indicator 75.

Within CAM 70, different vectors 72₀, 72₁, etc. can be stored in the bit cells of corresponding columns C0, C1, etc. in array 760. That is, within each column in array 760, bit values of a particular vector can be stored down the line in the first variable resistors of the bit cells. Opposite bit values can be stored down the line in the second variable resistors of the bit cells in the same column. During read operations concurrently directed to the columns, an input vector 71 can be applied to the rows. That is, bit values of the input vector 71 can be applied as data input signals (e.g., see Din₀, Din₁, and so on), in sequence, to the data input nodes for the rows. The number of bit values in each stored vector and in the input vector could be, for example, 100 (e.g., for a 100-bit CAM array) or any other suitable number. The amount of current flowing from each column to the corresponding ADC 755 during the read operations will be proportional to the sum of the resistances of the variable resistors through which current passes in the column. ADCs 755 can further generate and output corresponding digital output signals (e.g., see Dout₀, Dout₁, and so on) to comparator 73. Comparator 73 can further compare the received digital output signals and can generate and output a match indicator 75, which indicates the particular vector 72₀, 72₁, etc. that is stored in a particular column C0, C1, etc. and that most closely matches the input vector 71.

For example, those skilled in the art will recognize that a “hamming distance” refers to the number of mismatches between two vectors. With the above-described resistance summing operation, the resulting current across the sense node of a column will be inversely proportional to the hamming resistance. That is, the more closely matched a particular vector is to the input vector, the higher the resulting current will be (and, thus, the higher the corresponding digital output signal value). For example, as illustrated in the graph of FIG. 7B, reading of a stored vector (e.g., 72₀) may result in sensing of a current of approximately 100 nanoampheres (nA) passing through the bit cell stack of C0 and corresponding to hamming distance of 100 relative to one input vector 71, whereas reading of a different stored vector (e.g., 72₁) may result in sensing of a current of approximately 500 nA passing through the bit cell stack of C1 and corresponding to hamming distance of 0 (i.e., a perfect match) relative to the same input vector 71. If stored vector 72₁ is the perfect match, the match indicator 75 will indicate the column C1 corresponding to stored vector 72₁ and the highest sensed current and, thereby, the highest digital output signal value.

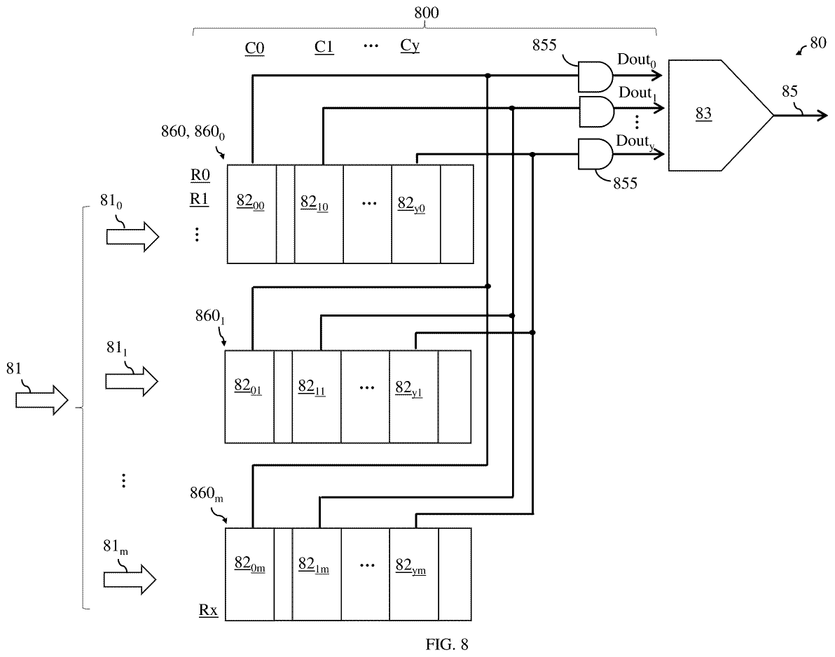

FIG. 8 is a schematic diagram illustrating a disclosed in-memory computing circuit structure (e.g., structure 100 of FIGS. 1, 200 of FIG. 3, or 300 of FIG. 3) implemented as a content addressable memory (CAM) 80 including array partitioning.

More particularly, referring to FIG. 8, a CAM 80 can include an in-memory computing structure 800 (e.g., such as structures 100 of FIGS. 1, 200 of FIG. 2, or 300 of FIG. 3 described in detail above). Generally, structure 800 includes, but is not limited to: an array 860 of bit cells arranged in column (e.g., C0-Cy) and rows (R0-Rx) (again as discussed in detail above and described in any of FIG. 1, 2 or 3); and ADCs 855 for the columns. It should be understood that some of the components of structure 800 have been omitted from CAM 80 of FIG. 8 in order to avoid clutter in the figures and allow the reader to focus on the salient aspects of the disclosed embodiment related specifically to partitioned CAM operation. In these embodiments, however, the array 860 of bit cells can be partitioned into multiple sub-arrays 860₀-860ₘ. Each sub-array 860₀-860ₘ can have the same columns C0-Cy, but can be split up (i.e., partitioned) into group of rows. For example, sub-array 860₀ can include first rows of bit cells, sub-array 860₁ can include second rows of rows, and so on. The numbers of rows in each sub-array can be the same or different and the last row in the last sub-array 860ₘ can correspond to the last row Rx in array 860. In these embodiments, each ADC 855 can be electrically connected to sense nodes on bit cell stacks of that same column in all of the corresponding sub-arrays 860₀-860ₘ. That is, the sense nodes on the bit cells stacks of C0 in sub-arrays 860₀-860ₘ can be connected to one ADC 855, sense nodes on the bit cell stacks of C1 in sub-arrays 860₀-860ₘ can be connected to another ADC 855, and so on. CAM 80 can further include a comparator 83. Comparator 83 can include: multiple input terminals, which are connected to receive digital output signals from ADCs 855 of the columns, respectively; and an output terminal for outputting a match indicator 73.

Within CAM 80, different vectors 82₀, 82₁, etc. can be stored in the bit cells of corresponding columns C0, C1, etc. In this case, the different vectors, like the array 860, can be partitioned. For example, for C0, a specific vector 82₀ can be partitioned into multiple segments 82₀₀-82₀ₘ with each vector segment being stored in the first variable resistors of the bit cells in the different rows in C0 of the different sub-array 860₀-860_{m.} For C1, another vector 82₁ can be partitioned into multiple segments 82₁₀-82₁ₘ with each vector segment being stored in the first variable resistors of the bit cells in the different rows in C1 of the different sub-array 860₀-860ₘ, and so on. During read operations concurrently directed to the columns, an input vector 81 can be partitioned into multiple segments 81₀-81ₘ with each vector segment being applied to the rows of the different sub-arrays 860₀-860ₘ. The amount of current flowing from the same column in each of the sub-arrays to the corresponding ADC 855 during the read operations will be proportional to the sum of the resistances of the variable resistors through which current passes in the same column across all sub-arrays. ADCs 855 can further generate and output corresponding digital output signals (e.g., see Dout₀, Dout₁, and so on) to comparator 83. Comparator 83 can further compare the received digital output signals and can generate and output a match indicator 85, which indicates the particular vector 82₀, 82₁, etc. that most closely matches the input vector 81 (e.g., in essentially the same manner as discussed above with regard to CAM 70 of FIG. 7A).

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
an array of bit cells in columns and rows, wherein each bit cell includes: end nodes; a first transistor and a first variable resistor connected in series between the end nodes; and a second transistor and a second variable resistor connected in series between the end nodes and wherein, within the columns, the bit cells are series-connected in bit cell stacks; and
sense nodes on the bit cell stacks; and
analog-to-digital converters connected to the sense nodes.

2. The structure of claim 1, wherein the first variable resistor and the second variable resistor are each any of a resistive random access memory (RRAM)-type variable resistor, a magnetic tunnel junction (MTJ)-type variable resistor, and a phase change memory (PCM)-type variable resistor.

3. The structure of claim 1, wherein the first variable resistor and the second variable resistor are independently switchable between different resistances.

4. The structure of claim 1, wherein one of the first variable resistor and the second variable resistor has a first resistance and a different one of the first variable resistor and the second variable resistor has a second resistance that is different from the first resistance.

5. The structure of claim 4, wherein the first resistance is lower than the second resistance and wherein the first resistance is indicative of a stored “1” bit value and the second resistance is indicative of a stored “0” bit value.

6. The structure of claim 1, further comprising:
first word line for the rows, respectively;
second word lines for the rows, respectively; and
inverters for the rows, respectively,
wherein each inverter is connected between a first word line for a row and a second word line for the row, and
wherein, within each bit cell in the row, a first gate of the first transistor is connected to the first word line for the row and wherein a second gate of the second transistor is connected to the second word line for the row.

7. The structure of claim 6, further comprising:
third word lines for the rows, respectively;
fourth word lines for the rows, respectively;
bit lines for the columns, respectively; and
source lines for the column, respectively,
wherein the end nodes include a first end node connected to the first transistor and the second transistor and a second end node connected to the first variable resistor and the second variable resistor, and
wherein each bit cell in the row and in a column further includes:
a third transistor connected between the first end node and a bit line for the column, wherein a third gate of the third transistor is connected to a third word line for the row; and
a fourth transistor connected between the second end node and a source line for the column, wherein a fourth gate of the fourth transistor is connected to a fourth word line for the row.

8. The structure of claim 7, wherein the first transistor, the second transistor, the third transistor, and the fourth transistor are N-type field effect transistors.

9. The structure of claim 6, further comprising:
third word lines for the rows, wherein at least some of the third word lines are shared between adjacent rows;
fourth word lines for the rows, wherein at least some of the fourth word lines are shared between adjacent rows;
bit lines for the columns, respectively; and
source lines for the column, respectively,
wherein the end nodes include a first end node connected to the first transistor and the second transistor and a second end node connected to the first variable resistor and the second variable resistor,
wherein each bit cell in the row and in a column further includes:
a third transistor connected between the first end node and a bit line for the column, wherein a third gate of the third transistor is connected to a third word line; and
a fourth transistor connected between the second end node and a source line for the column, wherein a fourth gate of the fourth transistor is connected to a fourth word line, and
wherein adjacent bit cells in different rows of a same column share one of the third transistor and the fourth transistor.

10. The structure of claim 6, further comprising pairs of bit lines and pairs of write word lines,
wherein all bit cells in each column are connected between a corresponding pair of the bit lines,
wherein adjacent columns are connected to a same bit line therebetween,
wherein all bit cells in each row are connected to a corresponding pair of the write word lines,
wherein adjacent rows are connected to a same write word line therebetween,
wherein each bit cell in the row and a column further includes:
a third transistor connected between one end node and one bit line for the column, wherein a third gate of the third transistor is connected to one write word line for the row; and
a fourth transistor connected between another end node and another bit line for the column, wherein a fourth gate of the fourth transistor is connected to another write word line for the row, and
wherein adjacent bit cells in different rows of a same column share one of the third transistor and the fourth transistor.

11. The structure of claim 1, wherein the bit cell stacks are connected between the analog-to-digital converters and footer devices and wherein the footer devices are connected to ground.

12. A structure comprising:
an array of bit cells in columns and rows, wherein each bit cell includes: end nodes; a first transistor and a first variable resistor connected in series between the end nodes; and a second transistor and a second variable resistor connected in series between the end nodes and wherein, within the columns, the bit cells are series-connected in bit cell stacks;
sense nodes on the bit cell stacks;
analog-to-digital converters connected to the sense nodes; and
a comparator connected to the analog-to-digital converters.

13. The structure of claim 12, wherein the first variable resistor and the second variable resistor are each any of a resistive random access memory (RRAM)-type variable resistor, a magnetic tunnel junction (MTJ)-type variable resistor, and a phase change memory (PCM)-type variable resistor.

14. The structure of claim 12, wherein the first variable resistor and the second variable resistor are independently switchable between different resistances.

15. The structure of claim 12, wherein one of the first variable resistor and the second variable resistor has a first resistance and a different one of the first variable resistor and the second variable resistor has a second resistance that is different from the first resistance, and wherein the first resistance is lower than the second resistance and wherein the first resistance is indicative of a stored “1” bit value and the second resistance is indicative of a stored “0” bit value.

16. The structure of claim 12, further comprising:
first word line for the rows, respectively;
second word lines for the rows, respectively; and
inverters for the rows, respectively,
wherein each inverter is connected between a first word line for a row and a second word line for the row, and
wherein, within each bit cell in the row, a first gate of the first transistor is connected to the first word line for the row and wherein a second gate of the second transistor is connected to the second word line for the row.

17. The structure of claim 16, further comprising:
third word lines for the rows, respectively;
fourth word lines for the rows, respectively;
bit lines for the columns, respectively; and
source lines for the column, respectively,
wherein the end nodes include a first end node connected to the first transistor and the second transistor and a second end node connected to the first variable resistor and the second variable resistor, and
wherein each bit cell in the row and in a column further includes:
a third transistor connected between the first end node and a bit line for the column, wherein a third gate of the third transistor is connected to a third word line for the row; and
a fourth transistor connected between the second end node and a source line for the column, wherein a fourth gate of the fourth transistor is connected to a fourth word line for the row.

18. The structure of claim 16, further comprising:
third word lines for the rows, wherein at least some of the third word lines are shared between adjacent rows;
fourth word lines for the rows, wherein at least some of the fourth word lines are shared between adjacent rows;
bit lines for the columns, respectively; and
source lines for the column, respectively,
wherein the end nodes include a first end node connected to the first transistor and the second transistor and a second end node connected to the first variable resistor and the second variable resistor,
wherein each bit cell in the row and in a column further includes:
a third transistor connected between the first end node and a bit line for the column, wherein a third gate of the third transistor is connected to a third word line; and
a fourth transistor connected between the second end node and a source line for the column, wherein a fourth gate of the fourth transistor is connected to a fourth word line, and
wherein adjacent bit cells in different rows of a same column share one of the third transistor and the fourth transistor.

19. The structure of claim 16, further comprising pairs of bit lines and pairs of write word lines,
wherein all bit cells in each column are connected between a corresponding pair of the bit lines,
wherein adjacent columns are connected to a same bit line therebetween,
wherein all bit cells in each row are connected to a corresponding pair of the write word lines,
wherein adjacent rows are connected to a same write word line therebetween,
wherein each bit cell in the row and in a column further includes:
a third transistor connected between one end node and one bit line for the column, wherein a third gate of the third transistor is connected to one write word line for the row; and
a fourth transistor connected between another end node and another bit line for the column, wherein a fourth gate of the fourth transistor is connected to another write word line for the row, and
wherein adjacent bit cells in different rows of a same column share one of the third transistor and the fourth transistor.

20. A structure comprising:
an array of bit cells arranged in columns and rows,
wherein each bit cell includes: end nodes; a first transistor and a first variable resistor connected in series between the end nodes; and a second transistor and a second variable resistor connected in series between the end nodes,
wherein the array is partitioned into multiple sub-arrays of the bit cells with each sub-array including a corresponding group of the rows, and
wherein, within each sub-array, the bit cells in the columns are series-connected in bit cell stacks;
sense nodes on the bit cell stacks;
analog-to-digital converters for the columns, wherein each analog-to-digital converter for a column is connected to all sense nodes on all bit cell stacks of the column in all the sub-arrays; and
a comparator connected to the analog-to-digital converters.
